(19) United States
(12) Patent Application Publication
(10) Pub. No.: US 2024/0388057 A1
(43) Pub. Date: Nov. 21, 2024

(54) WAVELENGTH VARIABLE LASER APPARATUS AND METHOD OF MANUFACTURING WAVELENGTH VARIABLE LASER APPARATUS

(71) Applicant: NEC Corporation, Tokyo (JP)

(72) Inventor: Naoki KOBAYASHI, Tokyo (JP)

(73) Assignee: NEC Corporation, Tokyo (JP)

(21) Appl. No.: 18/659,382

(22) Filed: May 9, 2024

(30) Foreign Application Priority Data
May 19, 2023 (JP) 2023-082702

(51) Int. Cl. H01S 5/0236; H01S 5/14

(52) U.S. Cl. CPC H01S 5/0236; H01S 5/141

(57) ABSTRACT

To provide a wavelength variable laser apparatus in which wet-spreading of an adhesive is suppressed when a semiconductor gain chip is mounted on a photonics element with an adhesive. A wavelength variable laser apparatus includes a semiconductor gain chip, a carrier on which the semiconductor gain chip is mounted, and a photonics element adhered to an end surface of the carrier with an adhesive. A lower end part in a longitudinal direction of the semiconductor gain chip is disposed in such a way as to face an upper end part in a longitudinal direction of the photonics element. Discontinuous shapes are formed on an area above a part of the end surface of the carrier to which the adhesive is applied.

### INCORPORATION BY REFERENCE

This application is based upon and claims the benefit of priority from Japanese patent application No. 2023-82702, filed on May 19, 2023, the disclosure of which is incorporated herein in its entirety by reference.

### TECHNICAL FIELD

The present disclosure relates to a wavelength variable laser apparatus and a method of manufacturing the wavelength variable laser apparatus.

### BACKGROUND ART

In many cases, a function of changing a wavelength of a laser to any wavelength is required for current optical communication in a region such as a mobile front-haul. Although there are various types of wavelength variable lasers, an external resonator type wavelength variable laser combining a semiconductor gain chip and a Si photonics element is considered as one of promising candidates from a viewpoint of characteristics and cost.

### CITATION LIST

### Patent Literature

[Patent Literature 1] Japanese Unexamined Patent Application Publication No. 2002-204025

### SUMMARY

The present invention provides a wavelength variable laser apparatus and a method of manufacturing the wavelength variable laser apparatus in which wet-spreading of an adhesive is suppressed when a semiconductor gain chip is adhered to a photonics element with the adhesive.

In a first example aspect of the present disclosure, a wavelength variable laser apparatus includes: a semiconductor gain chip; a carrier on which the semiconductor gain chip is mounted; and a photonics element adhered to an end surface of the carrier with an adhesive; wherein a lower end part in a longitudinal direction of the semiconductor gain chip is disposed in such a way as to face an upper end part in a longitudinal direction of the photonics element, and a discontinuous shape is formed in an area above a part of the end surface of the carrier to which the adhesive is applied.

In a second example aspect of the present disclosure, a method of manufacturing a wavelength variable laser apparatus includes: providing a carrier having a discontinuous shape on an end surface; mounting a semiconductor gain chip on an upper part of the carrier; adhering a photonics element to an area below the discontinuous shape of the end surface of the carrier with an adhesive; and disposing a lower end part in a longitudinal direction of the semiconductor gain chip in such a way as to face an upper end part in a longitudinal direction of the photonics element.

### BRIEF DESCRIPTION OF DRAWINGS

The above and other aspects, features, and advantages of the present disclosure will become more apparent from the following description of certain example embodiments when taken in conjunction with the accompanying drawings, in which:

FIG. 1 illustrates an example of a layout of a wavelength variable laser apparatus according to an example embodiment;

FIG. 2 is a diagram illustrating mounting of a semiconductor gain chip on a carrier according to a comparative example;

FIG. 3 is a diagram illustrating an example of a mounting structure according to a comparative example;

FIG. 4 is a diagram illustrating an example of a mounting structure for preventing wet-spreading of an adhesive according to the example embodiment;

FIG. 5 is a top view and a side view illustrating an example of a structure of a carrier using the present disclosure;

FIG. 6 is a diagram illustrating a discontinuous shape according to another example embodiment;

FIG. 7 is a diagram illustrating a discontinuous shape according to another example embodiment; and

FIG. 8 is a flowchart illustrating a method of manufacturing the wavelength variable laser apparatus according to the example embodiment.

### EXAMPLE EMBODIMENT

Hereinafter, a specific example embodiment to which the present disclosure is applied is described in detail with reference to the drawings. However, the present disclosure is not limited to the following embodiment. Further, for clarity of explanation, the following description and the drawings are simplified as appropriate.

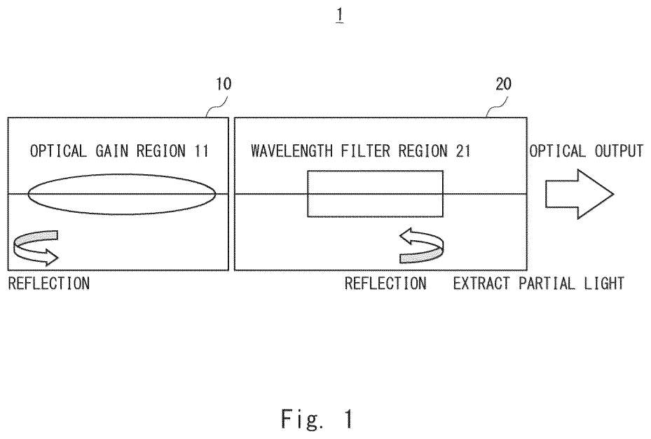

FIG. 1 illustrates an example of a layout of a wavelength variable laser apparatus. The wavelength variable laser apparatus illustrated in FIG. 1 is an external resonator type laser, and includes a semiconductor gain chip 10 and a Si photonics element 20. The semiconductor gain chip 10 is an element having an optical gain (optical gain region 11) therein. A wavelength filter region (and a light extraction region) 21 is provided inside the Si photonic element 20, and an oscillation wavelength of a laser can be determined by controlling a wavelength of light returning to the laser. It is necessary to precisely position and fix each element. This is called mounting.

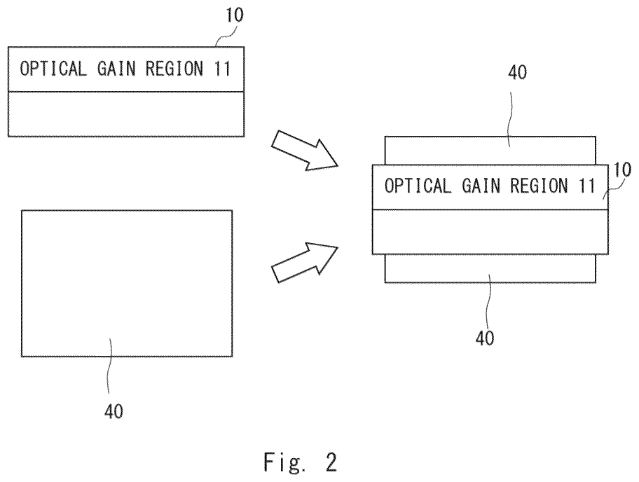

When the semiconductor gain chip 10 is mounted on the Si photonic element 20, as illustrated in FIG. 2, the semiconductor gain chip 10 is first mounted on a carrier. A thickness of the semiconductor gain chip 10 and A thickness of the Si photonic element 20 are often different from each other. Therefore, absorbing a difference in thickness is one of purposes of using the carrier 40. The carrier 40 may be made of a material such as aluminum nitride (AlN). After the semiconductor gain chip 10 is mounted on the carrier 40, an adhesive 30 is applied to an end surface of the carrier 40 and the carrier 40 is mounted on the Si photonics element 20. Examples of the adhesive 30 include, for example, an epoxy-based adhesive and an acrylic-based adhesive. In particular, the present disclosure may be effective in a case of an epoxy-based adhesive, which tends to wet-spread at low viscosity.

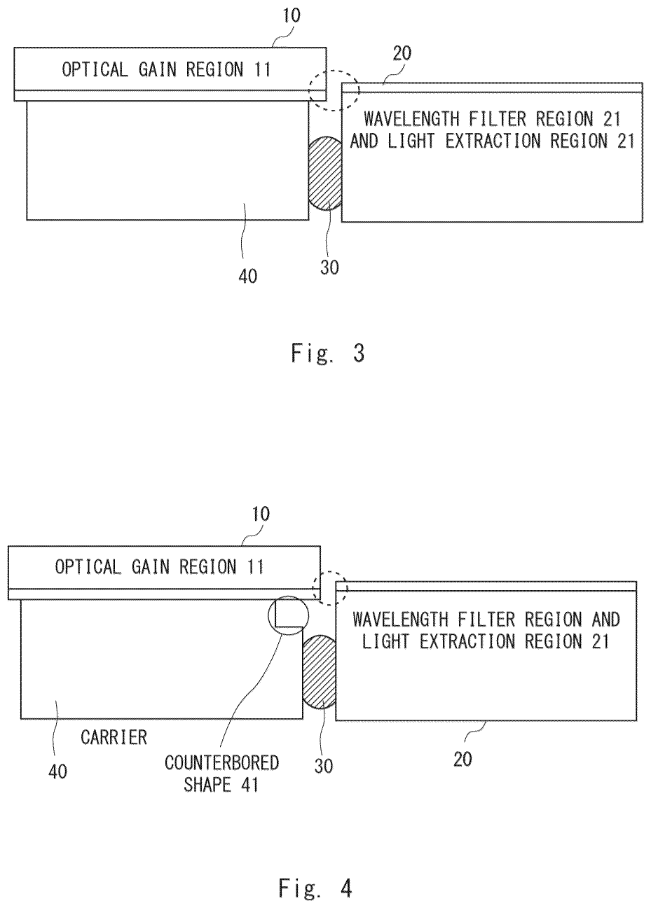

FIG. 3 is a diagram illustrating an example of a mounting structure according to a comparative example. The adhesive 30 is applied to a right end surface of the carrier 40, and is used for fixing the right end surface of the carrier 40 and a left end surface of the Si photonic element 20. When an application amount and an application shape of the adhesive 30 are not appropriately controlled, the adhesive 30 may wet-spread on an end surface of the semiconductor gain chip 10 and a part of the Si photonics element 20 where a wavelength filter or the like is located, and an optical characteristic may deteriorate. An adhesive should not be applied to an upper region between the carrier 40 and the Si photonic element 20, indicated by a dashed-line region in FIG. 3. Thus, the present disclosure proposes a method of controlling wet-spreading of an adhesive.

It is an object of the present disclosure to prevent wet-spreading of an adhesive. To that end, as illustrated in FIG. 4, a counterbored shape 41 is provided on at least a part of the upper part of the right end surface of the carrier 40. In principle, in order for the adhesive 30 to wet-spread, it is necessary that a surface with which the adhesive 30 is in contact be present continuously. When the surface in contact with the adhesive 30 is discontinuous, wet-spreading of the adhesive 30 is suppressed by a surface tension. A discontinuous shape such as a counterbored shape may be formed in a vicinity of an application region of the adhesive 30. One simple way to make a discontinuous shape is to form a level difference. An Adhesive should not be applied to the upper region between the carrier 40 and the Si photonic element 20, indicated by a dashed-line region in FIG. 4.

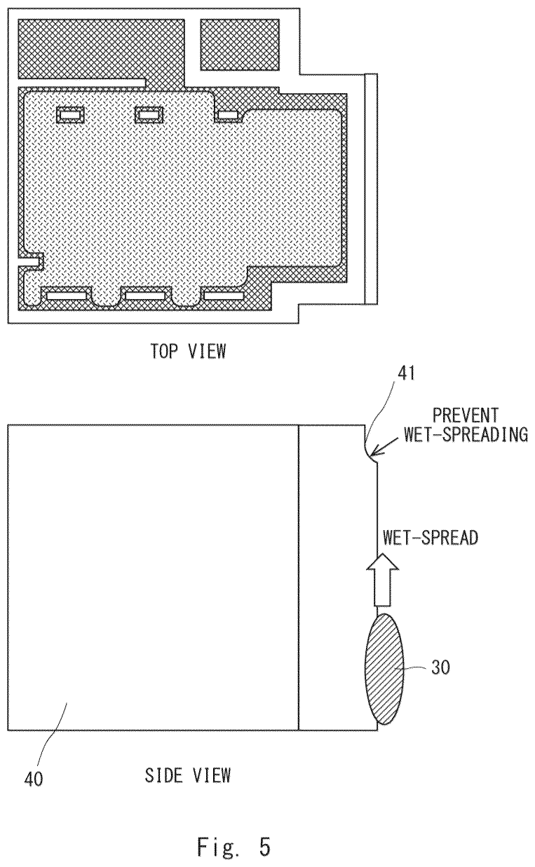

A presence of a level difference prevents the adhesive 30 from wet-spreading further, and as a result, wet-spreading of the adhesive 30 over the end surfaces of the semiconductor gain chip 10 and the Si photonics element 20 can be suppressed. As for the counterbored shape 41, a depth and a width thereof may be determined in consideration of a balance between a viscosity, an application amount, and an application area of the adhesive 30, and an optical characteristic. As an example, the depth of the counterbored shape 41 is assumed to be approximately 0.1 mm, and the width of the counterbored shape 41 is assumed to be approximately 0.03 to 0.05 mm, but the depth and the width of the counterbored shape are not limited thereto. An example of a carrier using the present disclosure is illustrated in FIG. 5. As illustrated in FIG. 5, by forming a counterbored shape on a corner part of the carrier 40, that is, the right end surface and an upper end surface, it is possible to easily manufacture a wavelength variable laser apparatus in which wet-spreading of an adhesive is suppressed.

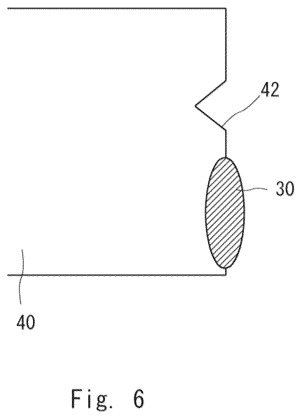

FIG. 6 illustrates a notched shape 42 formed in an area above a part of the right end surface of the carrier 40 to which the adhesive 30 is applied. In other example embodiment, two or more notches may be provided that differ in size and shape. For example, the notched shape 42 may be rectangular, semi-circular, or semi-elliptical.

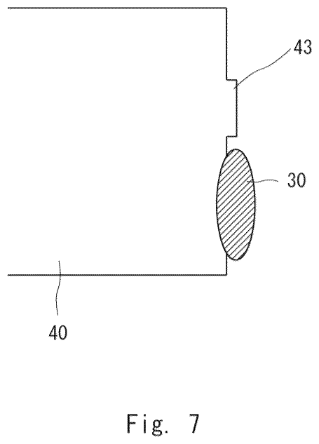

FIG. 7 illustrates a protrusion 43 formed on the area above the part of the right end surface of the carrier 40 to which the adhesive 30 is applied. In other example embodiment, two or more protrusions may be provided that differ in size and shape. For example, a shape of the protrusion 43 may be triangular, rectangular, semi-circular, or semi-elliptical.

As described above, by placing a discontinuous shape in a carrier, it is possible to prevent an adhesive from wet-spreading.

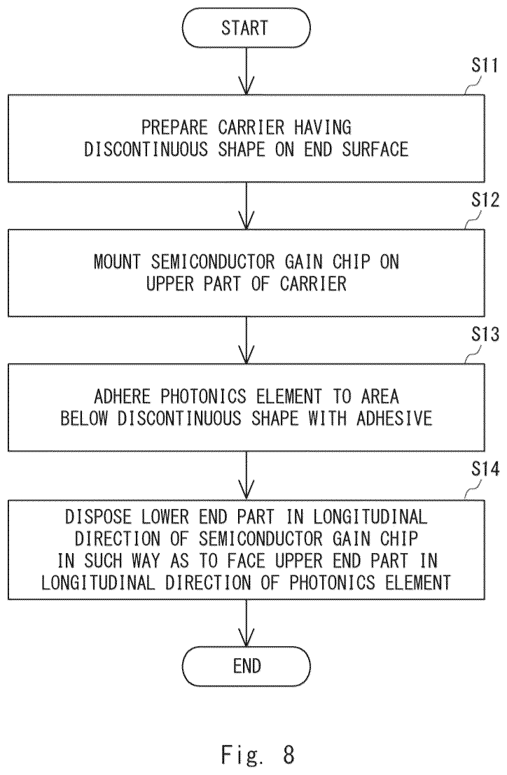

FIG. 8 is a flowchart illustrating a method of manufacturing the wavelength variable laser apparatus according to the example embodiment.

A carrier having a discontinuous shape on an end surface is prepared (step S11). A semiconductor gain chip is mounted on an upper part of the carrier (step S12). A photonics element is adhered to an area below the discontinuous shape on the end surface of the carrier with an adhesive (step S13). A lower end part in a longitudinal direction of the semiconductor gain chip is disposed in such a way as to face an upper end part in a longitudinal direction of the photonics element (step S14).

This makes it possible to easily manufacture a wavelength variable laser apparatus in which the wet-spreading of an adhesive is suppressed. In particular, by forming the above-described counterbored shape or notched shape, the wavelength variable laser apparatus can be more easily manufactured.

The present disclosure is not limited to the above-described example embodiment, and can be appropriately modified without departing from the scope of the present disclosure. Although the Si photonic element has been described in the above example embodiment, the present invention is applicable to a photonic element other than Si that can be understood by a person skilled in the art.

Some or all of the above-described embodiments may also be described as the following supplementary notes, but are not limited thereto.

### (Supplementary Note 1)

A wavelength variable laser apparatus including: a semiconductor gain chip;
a carrier on which the semiconductor gain chip is mounted; and
a photonics element being adhered to an end surface of the carrier with an adhesive, wherein
a lower end part in a longitudinal direction of the semiconductor gain chip is disposed in such a way to face an upper end part in a longitudinal direction of the photonics element, and
a discontinuous shape is formed in an area above a part of the end face of the carrier to which the adhesive is applied.

### (Supplementary Note 2)

The wavelength variable laser apparatus according to supplementary note 1, wherein the discontinuous shape is a counterbored shape formed on an area above a part of the end surface of the carrier to which the adhesive is applied, the area continuing to an upper surface of the carrier.

### (Supplementary Note 3)

The wavelength variable laser apparatus according to supplementary note 1, wherein the discontinuous shape is a notched shape formed on an area above a part of the end surface of the carrier to which the adhesive is applied.

### (Supplementary Note 4)

The wavelength variable laser apparatus according to supplementary note 1, wherein the discontinuous shape is a protrusion protruding above a part of the end surface of the carrier to which the adhesive is applied.

### (Supplementary Note 5)

The wavelength variable laser apparatus according to any one of supplementary notes 1 to 4, wherein the adhesive is an epoxy-based adhesive.

### (Supplementary Note 6)

A manufacturing method of a wavelength variable laser apparatus, including:
preparing a carrier having a discontinuous shape on an end surface;
mounting a semiconductor gain chip on an upper part of the carrier;
adhering a photonics element to an area below the discontinuous shape on the end surface of the carrier with an adhesive; and
disposing a lower end part in a longitudinal direction of the semiconductor gain chip in such a way as to face an upper end part in a longitudinal direction of the photonics element.

### (Supplementary Note 7)

The manufacturing method of a wavelength variable laser apparatus according to supplementary note 6, wherein the discontinuous shape is a counterbored shape formed on an area above a part of the end surface of the carrier on which the adhesive is applied, the area continuing to an upper surface of the carrier.

### (Supplementary Note 8)

The manufacturing method of a wavelength variable laser apparatus according to supplementary note 6, wherein the discontinuous shape is a notched shape formed on an area above a part of the end surface of the carrier to which the adhesive is applied.

### (Supplementary Note 9)

The manufacturing method of a wavelength variable laser apparatus according to supplementary note 6, wherein the discontinuous shape is a protrusion protruding above a part of the end surface of the carrier to which the adhesive is applied.

### (Supplementary Note 10)

The manufacturing method of a wavelength variable laser apparatus according to any one of supplementary notes 6 to 9, wherein the adhesive is an epoxy-based adhesive.

An example advantage according to the present disclosure is that a wavelength variable laser apparatus in which wet-spreading of an adhesive is suppressed and a method of manufacturing the wavelength variable laser apparatus can be provided.

What is claimed is:

1. A wavelength variable laser apparatus comprising:
a semiconductor gain chip;
a carrier on which the semiconductor gain chip is mounted; and
a photonics element being adhered to an end surface of the carrier with an adhesive, wherein
a lower end part in a longitudinal direction of the semiconductor gain chip is disposed in such a way as to face an upper end part in a longitudinal direction of the photonics element, and
a discontinuous shape is formed in an area above a part of the end face of the carrier to which the adhesive is applied.

2. The wavelength variable laser apparatus according to claim 1, wherein the discontinuous shape is a counterbored shape formed on an area above a part of the end surface of the carrier to which the adhesive is applied, the area continuing to an upper surface of the carrier.

3. The wavelength variable laser apparatus according to claim 1, wherein the discontinuous shape is a notched shape formed on an area above a part of the end surface of the carrier to which the adhesive is applied.

4. The wavelength variable laser apparatus according to claim 1, wherein the discontinuous shape is a protrusion protruding above a part of the end surface of the carrier to which the adhesive is applied.

5. The wavelength variable laser apparatus according to claim 1, wherein the adhesive is an epoxy-based adhesive.

6. A manufacturing method of a wavelength variable laser apparatus, comprising:
preparing a carrier having a discontinuous shape on an end surface;
mounting a semiconductor gain chip on an upper part of the carrier;
adhering a photonics element to an area below the discontinuous shape on the end surface of the carrier with an adhesive, and
disposing a lower end part in a longitudinal direction of the semiconductor gain chip in such a way as to face an upper end part in a longitudinal direction of the photonics element.

7. The manufacturing method of a wavelength variable laser apparatus according to claim 6, wherein the discontinuous shape is a counterbored shape formed on an area above a part of the end surface of the carrier to which the adhesive is applied, the area continuing to an upper surface of the carrier.

8. The manufacturing method of a wavelength variable laser apparatus according to claim 6, wherein the discontinuous shape is a notched shape formed on an area above a part of the end surface of the carrier to which the adhesive is applied.

9. The manufacturing method of a wavelength variable laser apparatus according to claim 6, wherein the discontinuous shape is a protrusion protruding above a part of the end surface of the carrier to which the adhesive is applied.

10. The manufacturing method of a wavelength variable laser apparatus according to claim 6, wherein the adhesive is an epoxy-based adhesive.
